(19) United States
(12) Patent Application Publication
(10) Pub. No.: US 2025/0366023 A1
(43) Pub. Date: Nov. 27, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroaki KATOU, Nonoichi Ishikawa (JP); Hirofumi KAWAI, Nonoichi Ishikawa (JP); Saya FUJINO, Kanazawa Ishikawa (JP); Takuya YASUTAKE, Kanazawa Ishikawa (JP); Hyuga SAITO, Nonoichi Ishikawa (JP); Atsushi KITO, Nonoichi Ishikawa (JP)

(21) Appl. No.: 18/885,539

(22) Filed: Sep. 13, 2024

(30) Foreign Application Priority Data
May 24, 2024 (JP) 2024-085155

(51) Int. Cl. H01L 29/78; H01L 29/40; H01L 29/66

(52) U.S. Cl. CPC H10D 30/665; H10D 30/0297; H10D 30/668; H10D 64/01; H10D 64/112; H10D 64/117

(57) ABSTRACT

A semiconductor device includes: a semiconductor portion having a cell region and a terminal region; a first electrode; a second electrode; a control electrode in the semiconductor portion via one of a plurality of first insulators arranged in a direction from the cell region to the terminal region; and a third electrode in the semiconductor portion via a second insulator between itself and the control electrode. The control electrode includes a first controller in contact with the first insulator, and a second controller in contact with the first insulator and opposed to the first controller via the second insulator. Among the plurality of first insulators, an adjacent insulator adjacent to the terminal insulator provided closer to the terminal region than to the control electrode has a slope inclined toward the lower side of the first controller, and the second controller is not present in the slope.

### CROSS-REFERENCE TO RELATED APPLICATIONS

This application is based upon and claims the benefit of priority from Japanese Patent Application No. 2024-085155, filed on May 24, 2024; the entire contents of which are incorporated herein by reference.

### FIELD

An embodiment of the present invention relates to a semiconductor device.

### BACKGROUND

In a semiconductor device such as a MOSFET having a trench gate, there is known a structure in which a field plate at the same potential as a source electrode is disposed together with the gate electrode inside a gate trench.

In the semiconductor device as described above, the gate electrode and the field plate are formed in a terminal region as well. At a final end of the terminal region, a terminal trench is further formed. If the withstand voltage of the gate electrode is insufficient in the vicinity of this terminal trench, reliability is deteriorated.

### BRIEF DESCRIPTION OF THE DRAWINGS

FIG. 1 is a cross-sectional view of a semiconductor device according to a first embodiment;

FIG. 2 is a cross-sectional view illustrating a process of forming an insulator on the inner surface of each of a trench and a terminal trench;

FIG. 3 is a cross-sectional view illustrating a process of forming a third electrode and a fourth electrode;

FIG. 4 is a cross-sectional view illustrating a process of etching a third electrode and a part of the fourth electrode;

FIG. 5 is a cross-sectional view illustrating a process of covering the upper surfaces of the third electrode and the fourth electrode with an insulator;

FIG. 6 is a cross-sectional view illustrating a process of filling the inside of the trench with an insulator;

FIG. 7 is a cross-sectional view illustrating a process of removing an upper part of the insulator;

FIG. 8 is a cross-sectional view illustrating a process of forming a gate insulator;

FIG. 9 is a cross-sectional view illustrating a process of forming a control electrode;

FIG. 10 is a cross-sectional view illustrating a process of forming a second semiconductor layer and a third semiconductor layer;

FIG. 11 is a cross-sectional view illustrating a process of dividing the control electrode into a first controller and a second controller;

FIG. 12 is a cross-sectional view illustrating a process of forming an insulator in a trench;

FIG. 13 is a cross-sectional view illustrating a process of forming a fourth semiconductor layer in the second semiconductor layer;

FIG. 14 is a cross-sectional view of a semiconductor device according to a comparative example;

FIG. 15 is a cross-sectional view of a semiconductor device according to a second embodiment;

FIG. 16 is a cross-sectional view illustrating a process of disposing resist on the terminal trench and on a trench adjacent to the terminal trench;

FIG. 17 is a cross-sectional view illustrating a process of leaving the control electrode;

FIG. 18 is a cross-sectional view illustrating a process of dividing the control electrode into a first controller and a second controller;

FIG. 19 is a cross-sectional view of a semiconductor device according to a third embodiment; and

FIG. 20 is a cross-sectional view illustrating a process of forming a gate insulator according to the third embodiment.

### DETAILED DESCRIPTION

Embodiments will now be explained with reference to the accompanying drawings. The present invention is not limited to the embodiments.

A semiconductor device according to an embodiment includes:
a semiconductor portion having a cell region and a terminal region provided outside the cell region;
a first electrode provided on a rear surface of the semiconductor portion;
a second electrode provided on a front surface side of the semiconductor portion;
a control electrode provided in the semiconductor portion via one of a plurality of first insulators arranged in a direction from the cell region to the terminal region; and
a third electrode provided in the semiconductor portion via a second insulator between itself and the control electrode, wherein
the control electrode includes a first controller in contact with the first insulator, and a second controller in contact with the first insulator and opposed to the first controller via the second insulator, and
among the plurality of first insulators, an adjacent insulator adjacent to the terminal insulator provided closer to the terminal region than to the control electrode has a slope inclined toward the lower side of the first controller, and there is no second controller in the slope.

### First Embodiment

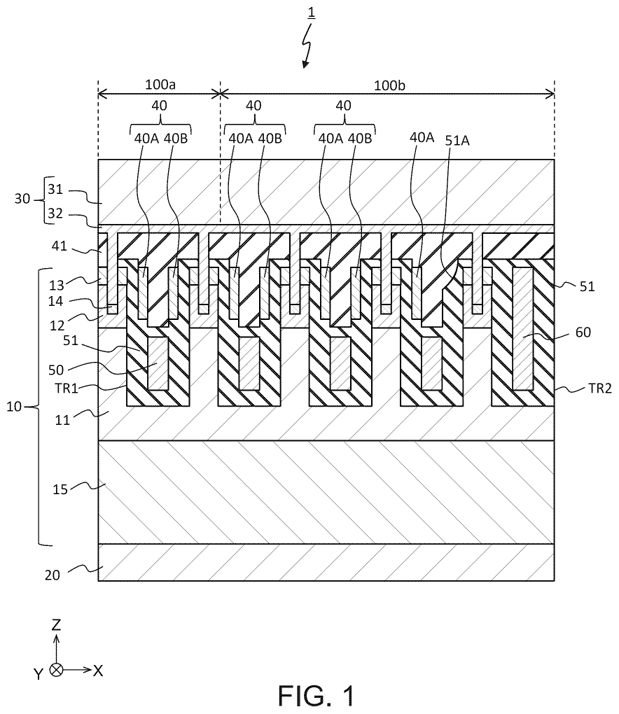

FIG. 1 is a cross-sectional view of a semiconductor device according to a first embodiment. In the following description, the arrangement and configuration of each part of the semiconductor device may be described using an X-axis, a Y-axis, and a Z-axis shown in each figure. The X-axis, the Y-axis, and the Z-axis are orthogonal to each other and represent X, Y, and Z directions, respectively. In addition, the Z direction may be described as an upward direction and the opposite direction thereof may be described as a downward direction. In the present embodiment, the X direction and the Y direction correspond to a first direction and a third direction and represent in-plane directions parallel to the front surface (or rear surface) of the semiconductor device 1. The Z direction corresponds to a second direction and represents an out-of-plane direction orthogonal to the front surface (or rear surface) of the semiconductor device 1.

Further, the notation of “p” and “p⁺” means that p-type impurity concentration increases in this order. Furthermore, the notation of “n⁻”, “n”, and “n⁺” means that the n-type impurity concentration increases in this order.

The impurity concentration can be measured, for example, by SIMS (Secondary Ion Mass Spectrometry). Further, the relative magnitude of impurity concentration can be determined, for example, from the magnitude of carrier concentration obtained by SCM (scanning capacitance microscopy). Further, a distance such as a depth of a semiconductor region can be obtained by SIMS, for example.

A semiconductor device 1 shown in FIG. 1 is, for example, a MOSFET. The semiconductor device 1 includes a semiconductor portion 10, a first electrode 20, a second electrode 30, a control electrode 40, a third electrode 50, and a fourth electrode 60.

The material of the semiconductor portion 10 is, for example, silicon. The semiconductor portion 10 includes, for example, a rear surface on which the first electrode 20 is provided, and a front surface opposite thereto. The second electrode 30 is provided on the front surface side of the semiconductor portion 10. The first electrode 20 is a drain electrode.

The first electrode 20 is provided on the rear surface of the semiconductor portion 10. The second electrode 30 is a source electrode and has a metal layer 31 and a barrier metal layer 32. The metal layer 31 is made of, for example, aluminum (Al). On the other hand, the barrier metal layer 32 is formed of, for example, a layered product of titanium (Ti) and titanium nitride (TiN). The semiconductor portion 10 includes a cell region 100a and a terminal region 100b.

The cell region 100a switches between an on-state and an off-state according to the voltage applied to the control electrode 40. In the on state, a current path is formed through which current flows from the first electrode 20 to the second electrode 30. In the off state, since the current path is not formed, current does not flow from the first electrode 20 to the second electrode 30.

The terminal region 100b is provided outside the cell region 100a. In the terminal region 100b, the above described current path is not formed regardless of whether or not voltage is applied to the control electrode 40 so that current does not flow from the first electrode 20 to the second electrode 30.

The semiconductor portion 10 includes a first semiconductor layer 11 of a first conductivity type, a second semiconductor layer 12 of a second conductivity type, a third semiconductor layer 13 of a first conductivity type, a fourth semiconductor layer 14 of a second conductivity type, and a fifth semiconductor layer 15 of a first conductivity type. In the present embodiment, the first conductive type is an n-type and the second conductive type is a p-type.

The first semiconductor layer 11 is an n⁻-type drift layer. The first semiconductor layer 11 is provided between the first electrode 20 and the second electrode 30.

The second semiconductor layer 12 is a p-type diffusion layer. The second semiconductor layer 12 is provided on the first semiconductor layer 11.

The third semiconductor layer 13 is an n⁺-type source layer. The third semiconductor layer 13 is provided on the second semiconductor layer 12. The third semiconductor layer 13 contains a first conductivity type impurity at a concentration higher than the first conductivity-type impurity concentration of the first semiconductor layer 11 and is electrically connected to the second electrode 30. The third semiconductor layer 13 is provided in the cell region 100a but is not provided in the terminal region 100b.

The fourth semiconductor layer 14 is a p⁺-type contact layer. The 35 fourth semiconductor layer 14 is connected to the second electrode 30 in the second semiconductor layer 12. The fourth semiconductor layer 14 contains a second conductivity type impurity in a higher concentration than the second conductivity impurity concentration of the second semiconductor layer 12 and is electrically connected to the second electrode 30. In the present embodiment, the fourth semiconductor layer 14 is provided in the second semiconductor layer 12. The second semiconductor layer 12 is electrically connected to the second electrode 30 via the fourth semiconductor layer 14.

The fifth semiconductor layer 15 is an n-type drain layer. The fifth semiconductor layer 15 is provided between the first semiconductor layer 11 and the first electrode 20. The fifth semiconductor layer 15 contains a first conductivity-type impurity at a concentration higher than the first conductive impurity concentration of the first semiconductor layer 11 and is electrically connected to the first electrode 20.

The control electrode 40 provided in the cell region 100a is a gate electrode. The control electrode 40 is located between the first electrode 20 and the second electrode 30 and is provided inside the trench TR1 opened at the front surface of the semiconductor portion 10. On the other hand, in the terminal region 100b, as described above, the third semiconductor layer 13 is not provided in the terminal region 100b. Therefore, the control electrode 40 provided in the terminal region 100b is a dummy gate electrode.

The third electrode 50 is a field plate. The third electrode 50 is electrically connected to the second electrode 30 and is provided inside the trench TR1 away from the control electrode 40. The third electrode 50 is provided, for example, to be located in the first semiconductor layer 11. In the trench TR1, the distance from the third electrode 50 to the first electrode 20 is shorter than the distance from the control electrode 40 to the first electrode 20.

As shown in FIG. 1, the control electrode 40 is provided at the same level as the second semiconductor layer 12 in the direction from the first electrode 20 to the second electrode 30, that is, in the Z direction. The control electrode 40 includes a first controller 40A and a second controller 40B. The first controller 40A and the second controller 40B are lined up in the X direction inside the trench TR1. However, while a first controller 40A is provided in the control electrode 40 disposed outermost in the terminal region 100b, the second controller 40B is not provided.

The trench TR1 extends in the X direction from the second electrode 30 to the first electrode 20 and has a depth from the front surface side of the semiconductor portion 10 up to the inside of the first semiconductor layer 11.

The terminal trench TR2 is provided at the outermost final end of the terminal region 100b. The terminal trench TR2 has a depth equivalent to that of the trench TR1. A fourth electrode 60 is provided in the terminal trench TR2. The length of the fourth electrode 60 in the Z direction is longer than that of the third electrode 50. In other words, the thickness of the fourth electrode 60 is thicker than that of the third electrode 50.

Note that the fourth electrode 60 may be continuously formed so as to surround the entire circumference of the cell region 100a or may be intermittently formed so as to partially surround the circumference of the cell region 100a. Further, although the cell region 100a is surrounded by one fourth electrode 60 in a single layer in FIG. 1, the cell region 100a may be surrounded by a plurality of fourth electrodes 60 in multiple layers.

In the present embodiment, a plurality of trenches TR1 are provided side by side in the X direction in each of the cell region 100a and the terminal region 100b. The second semiconductor layer 12 is provided between the plurality of trenches TR1, respectively, and is opposed to the first controller 40A and the second controller 40B of the control electrode 40 via the insulator 51.

As shown in FIG. 1, the semiconductor device 1 further includes an insulator 41 and an insulator 51. In the present embodiment, the insulator 41 corresponds to the second insulator, and the insulator 51 corresponds to the first insulator.

The insulator 41 is provided so as to cover the first controller 40A and the second controller 40B in the trench TR1. Further, the insulator 41 is provided between the second electrode 30 and the control electrode 40 and functions as an interlayer insulator that electrically insulates the control electrode 40 from the second electrode 30. Further, the insulator 41 is provided between the semiconductor portion 10 and the third electrode 50 and electrically insulates the third electrode 50 from the semiconductor portion 10.

The insulator 51 is provided between the semiconductor portion 10 and the control electrode 40 and functions as a gate insulator that electrically insulates the control electrode 40 from the semiconductor portion 10. The second semiconductor layer 12 is provided so as to be opposed to the control electrode 40 via the gate insulator. The third semiconductor layer 13 comes into contact with the gate insulator between the second semiconductor layer 12 and the second electrode 30. Further, the insulator 51 is provided between the insulator 41 and the third electrode 50. Further, in the terminal region 100b, the insulator 51 provided in the TR1 adjacent to the terminal trench TR2 has a slope 51A. The slope 51A is inclined toward the lower side of the first controller 40A. Further, the insulator 51 covers the fourth electrode 60 in the terminal trench TR2. The insulator 51 formed on the inner surface of the terminal trench TR2 is also referred to as a terminal insulator. Further, the insulator 51 formed on the inner surface of the trench TR1 adjacent to the terminal trench TR2 is also referred to as an adjacent insulator.

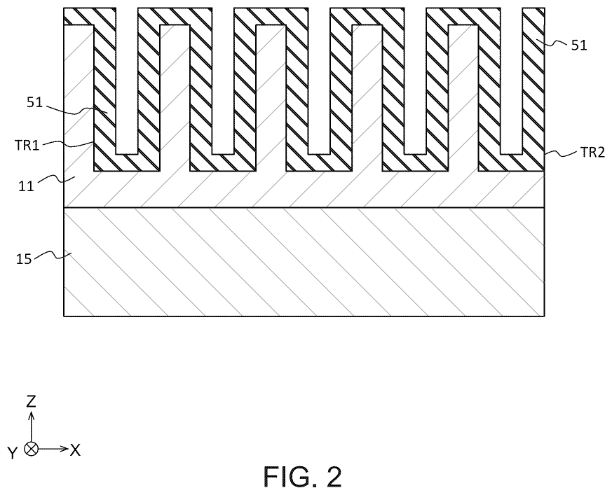

Hereinafter, with reference to FIGS. 2 to 13, a manufacturing method of the semiconductor device 1 according to the present embodiment will be described. Here, the process after forming the trench TR1 and the terminal trench TR2 will be described.

First, as shown in FIG. 2, an insulator 51 is formed on the inner surface of each of the trench TR1 and the terminal trench TR2. The insulator 51 is formed using, for example, silicon oxide (SiO₂).

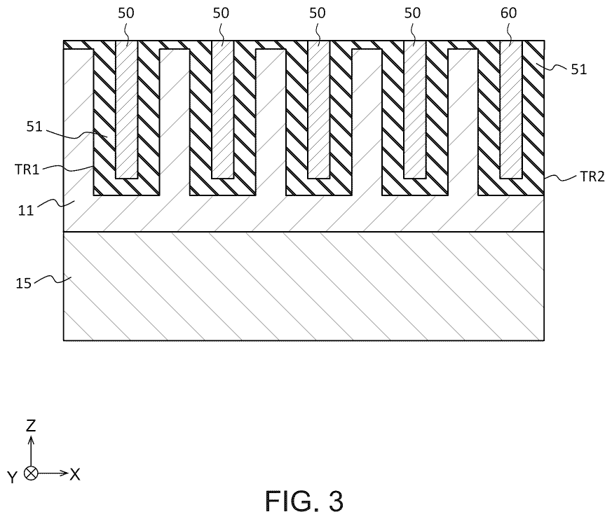

Next, as shown in FIG. 3, a third electrode 50 is formed in the trench TR1 and a fourth electrode 60 is formed in the terminal trench TR2. The third electrode 50 and the fourth electrode 60 are formed, for example, as simultaneously formed polysilicon films. In the present embodiment, the third electrode 50 and the fourth electrode 60 are simultaneously formed polysilicon films.

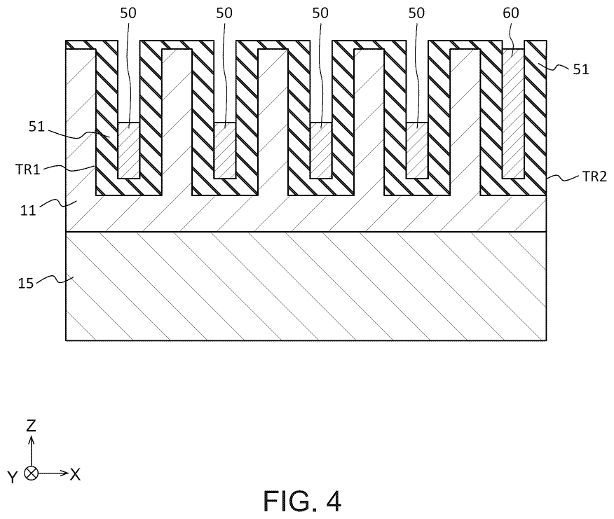

Next, as shown in FIG. 4, the third electrode 50 is etched, for example, by CDE (chemical dry etching). At this time, the third electrode 50 is etched while the fourth electrode 60 is protected with a resist so as not be etched.

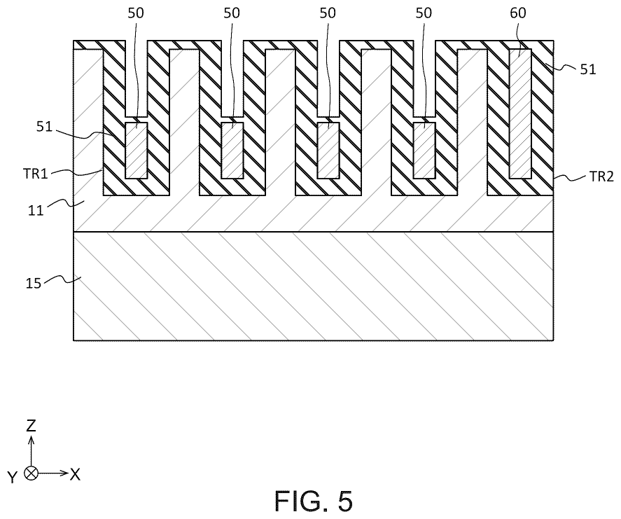

Next, as shown in FIG. 5, upper surfaces (exposed surfaces) of the third electrode 50 and the fourth electrode 60 are covered with an insulator 51. At this time, the upper end of the trench TR1 is open, while the upper end of the terminal trench TR2 is blocked with the insulator 51.

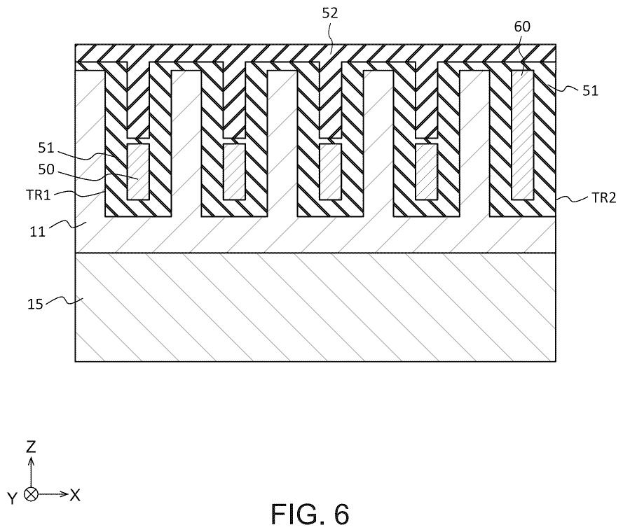

Next, as shown in FIG. 6, the upper surface of the insulator 51 is covered with the insulator 52, and the inside of the trench TR1 is filled with the insulator 52. The insulator 52 corresponds to a third insulator and is formed using, for example, BPSG (boron phosphorus silicon glass). Note that, the portion of the insulator 52 covering the upper surface of the insulator 51 is removed by, for example, a CMP (chemical mechanical polisher). As a result, the insulator 52 filled in the trench TR1 remains.

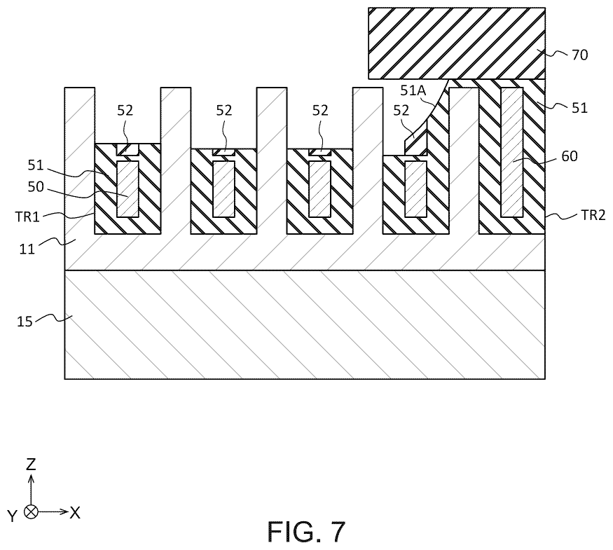

Next, as shown in FIG. 7, a portion located above the third electrode 50 in the insulator 51 formed in the trench TR1 and an insulator 52 surrounded by that portion are etched. In this process, resist 70 is used to protect the insulator 51 formed on top of the terminal trench TR2. The resist 70 is formed so as to also cover the upper part of the trench TR1 adjacent to the terminal trench TR2. However, due to side etching, the insulator 51 and the insulator 52 are scraped in a fan-shape in the trench TR1. As a result, a slope 51A is formed on an inner side surface of the trench TR1.

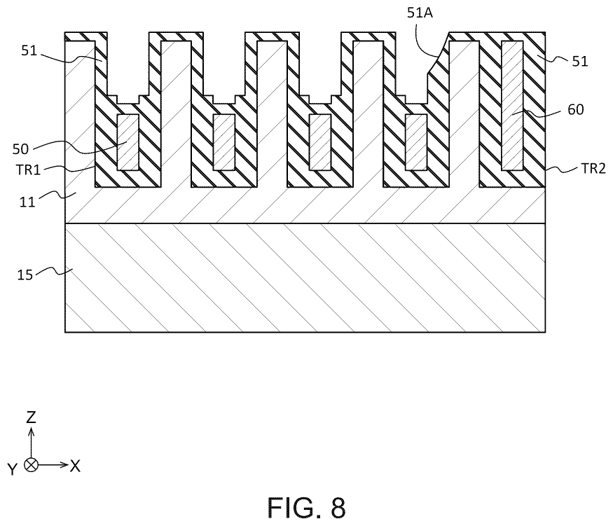

Next, as shown in FIG. 8, the insulator 52 is removed, and subsequently an insulator 51 that functions as a gate insulator is formed in the trench TR1. At this time, as shown in FIG. 8, in the trench TR1 adjacent to the terminal trench TR2 in the terminal region 100b, the insulator 52 formed in the slope 51A is removed as well.

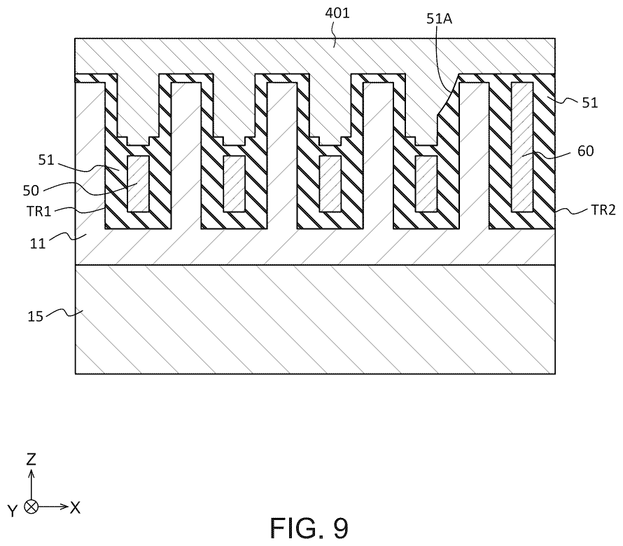

Next, as shown in FIG. 9, polysilicon 401 is filled in the trench TR1, and its film is formed on the upper surface of the insulator 51.

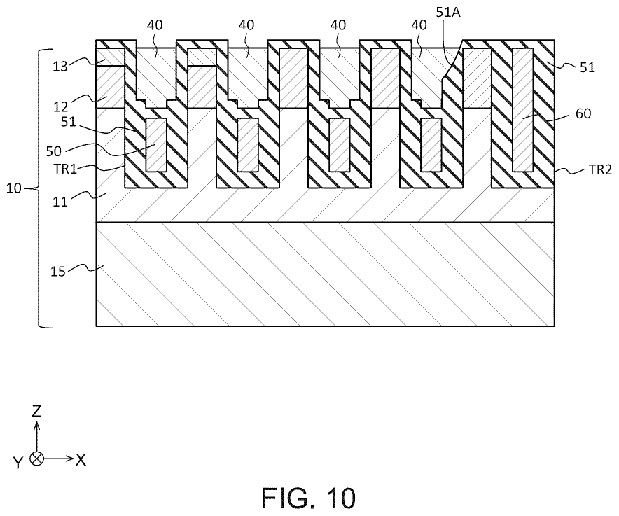

Next, as shown in FIG. 10, the polysilicon 401 formed on the upper surface of the insulator 51 is etched to leave the control electrode 40 which is the polysilicon 401 filled in the trench TR1. The polysilicon 401 is removed, for example, by CDE. Subsequently, a second semiconductor layer 12 is formed on top of the first semiconductor layer 11. The second semiconductor layer 12 can be formed, for example, by implanting and diffusing p-type impurities. Subsequently, a third semiconductor layer 13 is formed on top of the second semiconductor layer 12. The third semiconductor layer 13 can be formed, for example, by implanting and diffusing n-type impurities. However, while the third semiconductor layer 13 is formed in the cell region 100a, it is not formed in the terminal region 100b.

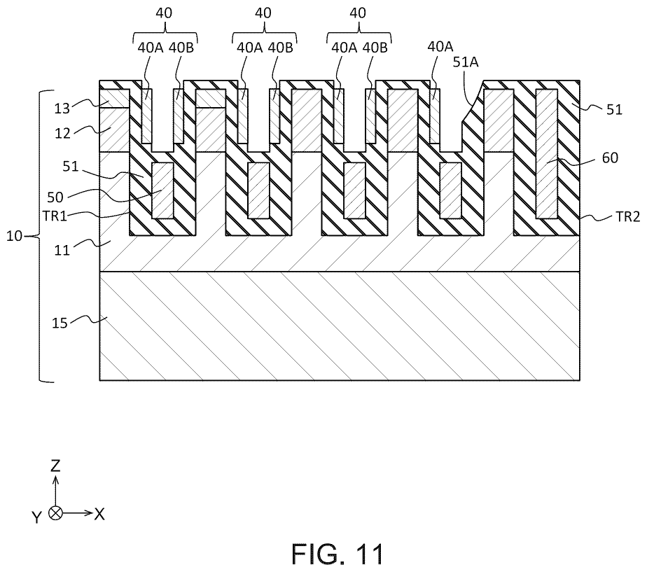

Next, as shown in FIG. 11, a central portion of the control electrode 40 is removed. As a result, the control electrode 40 is divided into a first controller 40A and a second controller 40B. However, in the control electrode 40, a portion formed on the slope 51A of the insulator 51 is removed as well. Therefore, in the trench TR1 adjacent to the terminal trench TR2, the first controller 40A remains. Note that since the first controller 40A and the second controller 40B are connected at a terminal portion in the Y direction (depth direction), the electrical connection of the first controller 40A and the second controller 40B is maintained.

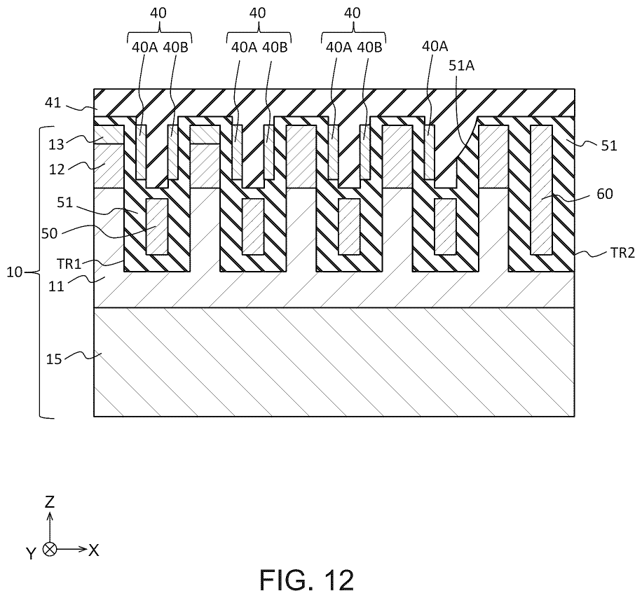

Next, as shown in FIG. 12, an insulator 41 is formed in the trench TR1. The insulator 41 can be formed by CVD (chemical vapor deposition) using, for example, a non-doped BPSG.

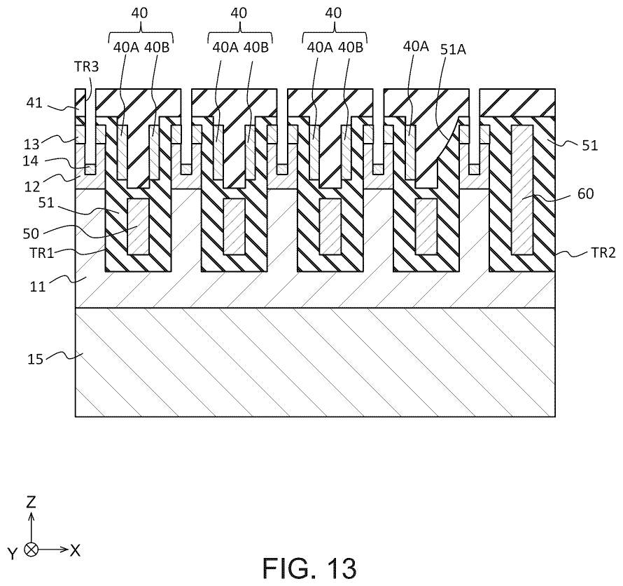

Next, as shown in FIG. 13, a fourth semiconductor layer 14 is formed in the second semiconductor layer 12. The fourth semiconductor layer 14 can be formed, for example, by forming a trench TR3 which penetrates the insulator 41 and the third semiconductor layer 13 in the Z direction and is terminated at the second semiconductor layer 12, and subsequently implanting and diffusing p-type impurities from the trench TR3.

Finally, returning to FIG. 1, the first electrode 20 and the second electrode 30 are formed. As a result, the semiconductor device 1 shown in FIG. 1 is completed.

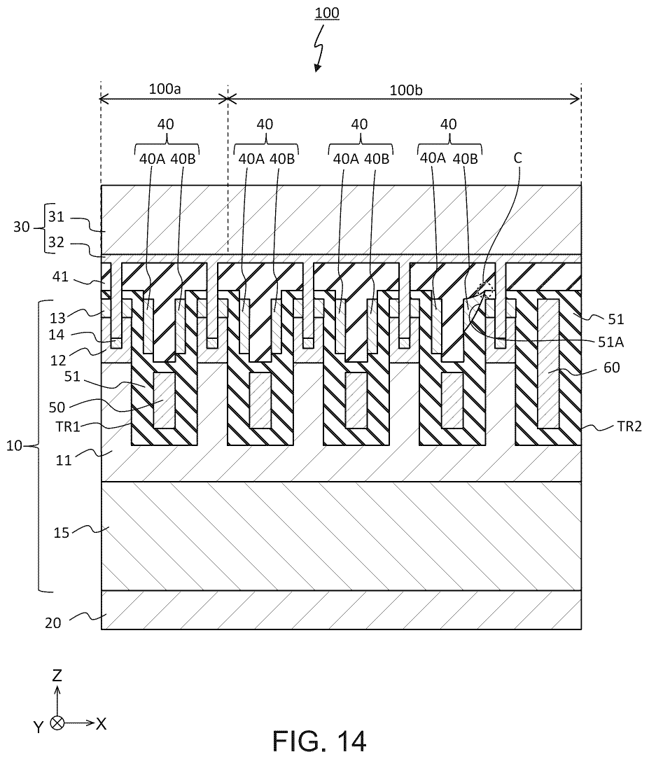

Here, a comparative example to be compared with the present embodiment will be described. FIG. 14 is a cross-sectional view of a semiconductor device according to a comparative example. In FIG. 14, the same components as those of the semiconductor device 1 described above are denoted by the same reference numerals, thereby omitting duplicate descriptions thereof.

In the semiconductor device 100 shown in FIG. 14, the second controller 40B is formed in the slope 51A as well. The slope 51A has a shape inclined toward the lower side of the first controller 40A. Therefore, the right upper-end part of the terminal trench TR2 side in the second controller 40B formed in the slope 51A (see a region C surrounded by a circle in FIG. 14) has a pointed shape. Since, for that reason, the electric field tends to be concentrated on the oxide film (insulators 41 and 51) in contact with the pointed portion, the life of the oxide film may deteriorate. As a result, long-term reliability for withstand voltage may be insufficient.

On the other hand, in the present embodiment, as shown in FIG. 11, the control electrode 40 formed in the slope 51A is removed. Therefore, there is no second controller 40B in the slope 51A. Therefore, according to the present embodiment, it is possible to improve reliability.

### Second Embodiment

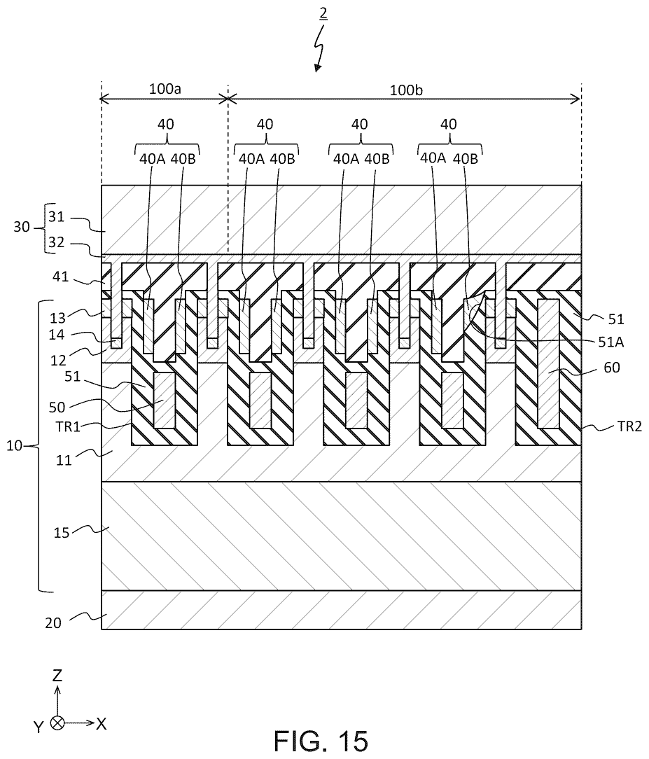

FIG. 15 is a cross-sectional view of a semiconductor device according to a second embodiment. In FIG. 15, the differences from the semiconductor device 1 according to the first embodiment described above will be mainly described. The same components as those of the semiconductor device 1 according to the first embodiment are denoted by the same reference numerals, thereby omitting duplicate descriptions.

In the semiconductor device 2 according to the present embodiment, the control electrode 40 provided in the trench TR1 adjacent to the terminal region 100b also has a second controller 40B in addition to the first controller 40A. This second controller 40B is present on the slope 51A.

The control electrode 40 provided in the above described trench TR1 is made of polysilicon containing impurities in the same manner as the control electrode 40 provided in other trenches TR1. On the other hand, the concentration of impurities contained in the control electrode 40 provided in the above described trench TR1 is lower than the concentration of impurities contained in the control electrode 40 provided in other trenches TR1. For example, the control electrode 40 provided in the above described trench TR1 may be made of non-doped polysilicon which does not contain impurities.

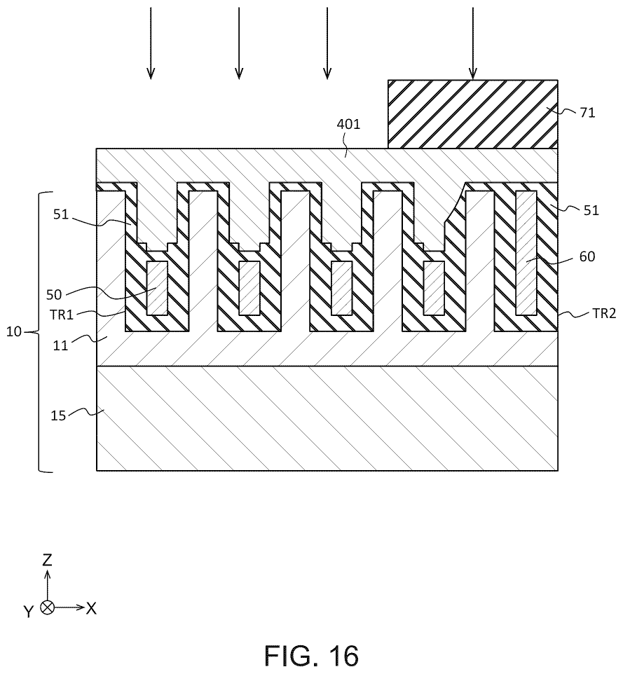

Hereinafter, with reference to FIGS. 16 to 18, a manufacturing method of the semiconductor device 2 according to the present embodiment will be described. Here, the differences from the first embodiment will be mainly described.

Since the process of filling the polysilicon 401 in the trench TR1 and forming a film on the upper surface of the insulator 51 (see FIG. 9) is the same as in the first embodiment, description thereof is omitted. The polysilicon 401 is a non-doped polysilicon which does not contain impurities.

Next, as shown in FIG. 16, a resist 71 is placed on the terminal trench TR2 and on the trench TR1 adjacent to the terminal trench TR2. Subsequently, for example, phosphorus (P) is ion-implanted from above as an impurity (see the arrows in FIG. 16). At this time, since the resist 71 functions as a mask, implantation of phosphorus into the portion of the polysilicon 401 formed on the terminal trench TR2 and the portion thereof formed in the trench TR1 adjacent to the terminal trench TR2 are blocked.

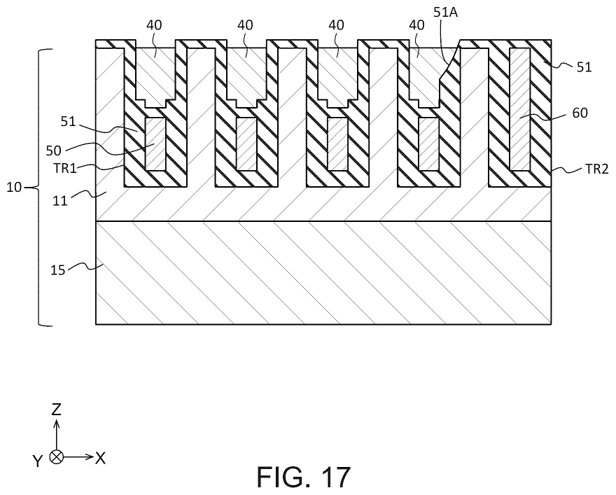

Next, the resist 71 is peeled off. Subsequently, as shown in FIG. 17, the polysilicon 401 formed on the upper surface of the insulator 51 is etched to leave a control electrode 40 which is a polysilicon 401 filled in the trench TR1. At this time, the control electrode 40 formed in the trench TR1 adjacent to the terminal trench TR2 is made of non-doped polysilicon, while the control electrode 40 formed in other trenches TR1 is made of polysilicon containing phosphorus as an impurity.

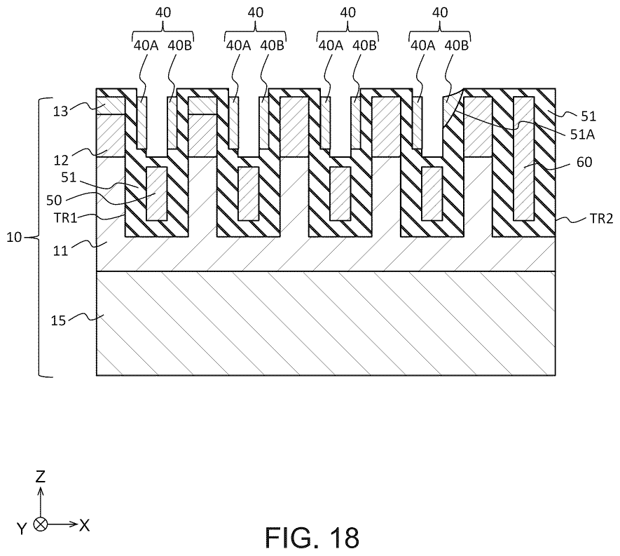

Next, as shown in FIG. 18, as in the first embodiment, a second semiconductor layer 12 is formed on top of the first semiconductor layer 11 and a third semiconductor layer 13 is formed on top of the second semiconductor layer 12. Subsequently, the central portion of the control electrode 40 is removed in the same manner as in the first embodiment. However, in the present embodiment, as shown in FIG. 18, the control electrode 40 formed in the slope 51A remains. Therefore, in the trench TR1 adjacent to the terminal trench TR2, the first controller 40A and the second controller 40B remain. Note that since the first controller 40A and the second controller 40B formed in the trench TR1 adjacent to the terminal trench TR2 are also connected at a terminal portion in the Y direction (depth direction), the electrical connection of the first controller 40A and the second controller 40B is maintained. Since the subsequent processes are the same as those of the first embodiment, description thereof will be omitted.

In the semiconductor device 2 according to the present embodiment described above, a second controller 40B is provided in the slope 51A of the trench TR1 adjacent to the terminal trench TR2. If the concentration of impurity (phosphorus) contained in the second controller 40B is high, enhanced oxidation of the second controller 40B is promoted. In this case, since the right upper-end part of the second controller 40B has a more pointed-shape, the electric field is more likely to be concentrated on the oxide film in contact with the right upper-end part. As a result, the life of this oxide film may be shortened, resulting in insufficient long-term reliability for withstand voltage.

On the other hand, in the present embodiment, the impurity concentration of the second controller 40B formed in the slope 51A as described above is lower than the impurity concentration of other second controllers 40B. As a result, the enhanced oxidation of the second controller 40B is suppressed, and the degree of protrusion of the right upper-end part is also suppressed. Since, as a result, the electric field concentration on the oxide film is reduced, it becomes possible to improve reliability.

### Third Embodiment

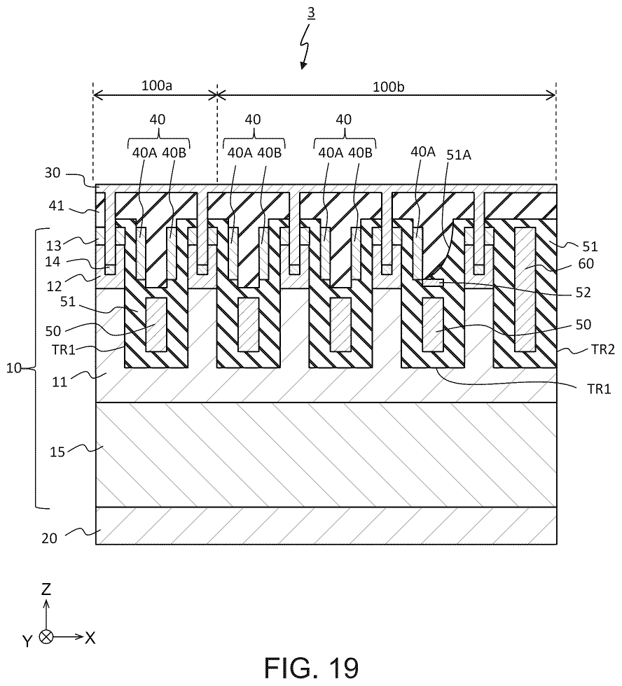

FIG. 19 is a cross-sectional view of a semiconductor device according to a third embodiment. In FIG. 19, differences from the semiconductor device 1 according to the first embodiment described above will be mainly described. The same components as those of the semiconductor device 1 according to the first embodiment are denoted by the same reference numerals, and duplicate descriptions thereof will be omitted.

In a semiconductor device 3 according to the present embodiment, the lower end position of the slope 51A is different from the first embodiment in the trench TR1 adjacent to the terminal region 100b. In the semiconductor device 1 according to the first embodiment described above, as shown in FIG. 1, the slope 51A is opposed to the first controller 40A in the X direction via the insulator 41. At this time, the lower end of the insulator 41 is located lower than the lower end of the slope 51A.

On the other hand, in the semiconductor device 3 according to the present embodiment, as shown in FIG. 19, an insulator 52 is provided between the third electrode 50 and the slope 51A. Therefore, the lower end of the slope 51A is elongated to be closer to the lower end of the first controller 40A compared with the first embodiment. That is, in the cross-sectional view of FIG. 19, the lower end of the slope 51A is elongated to the left side.

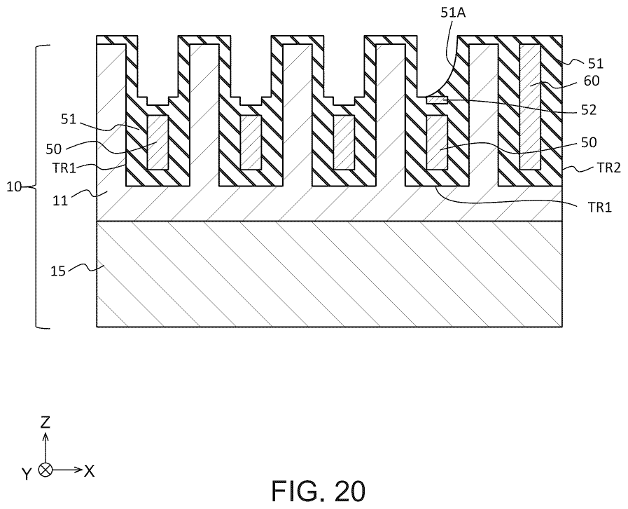

Hereinafter, with reference to FIG. 20, a manufacturing method of the semiconductor device 3 according to the present embodiment will be described. Here, the differences from the first embodiment will be mainly described.

In the present embodiment, the processes from the process of forming the trench TR1 and the terminal trench TR2 (see FIG. 2) to the process of etching the upper part of the insulator 51 and the upper part of the insulator 52 formed in the trench TR1 (see FIG. 7) are the same as in the first embodiment. Therefore, description thereof will be omitted.

Next, in the present embodiment, as shown in FIG. 20, the insulator 51 is left in the trench TR1 adjacent to the terminal trench TR2, and the insulator 52 of other trenches TR1 is removed.

Subsequently, an insulator 51 functioning as a gate insulator is formed in the trench TR1. At this time, as shown in FIG. 20, in the trench TR1 adjacent to the terminal trench TR2, a slope 51A is formed on the insulator 52. Therefore, the lower end of the slope 51A is elongated to the left side in the X direction, that is, to the first controller 40A side, compared with the first embodiment.

Since the subsequent processes (FIGS. 9 to 13) are the same as those of the first embodiment, description thereof is omitted. Finally, returning to FIG. 19, the first electrode 20 and the second electrode 30 are formed. As a result, the semiconductor device 3 shown in FIG. 19 is completed.

In the present embodiment described above, as in the first embodiment, there is no second controller 40B in the slope 51A. Therefore, according to the present embodiment, it becomes possible to improve reliability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device, comprising:
a semiconductor portion having a cell region and a terminal region provided outside the cell region;
a first electrode provided on a rear surface of the semiconductor portion;
a second electrode provided on a front surface side of the semiconductor portion;
a control electrode provided in the semiconductor portion via one of a plurality of first insulators arranged in a direction from the cell region to the terminal region; and
a third electrode provided in the semiconductor portion via a second insulator between itself and the control electrode, wherein
the control electrode includes a first controller in contact with the first insulator, and a second controller in contact with the first insulator and opposed to the first controller via the second insulator, and
among the plurality of first insulators, an adjacent insulator adjacent to the terminal insulator provided closer to the terminal region than to the control electrode has a slope inclined toward the lower side of the first controller, and there is no second controller in the slope.

2. The semiconductor device according to claim 1, wherein
in the adjacent insulator, the slope is opposed to the first controller via the second insulator, and the lower end of the second insulator is located lower than the lower end of the slope.

3. The semiconductor device according to claim 1, wherein
in the adjacent insulator, the slope is opposed to the first controller via the second insulator, and
the semiconductor device further comprises a third insulator provided between the slope and the third electrode.

4. The semiconductor device according to claim 1, wherein the semiconductor portion includes:
a first semiconductor layer provided with the terminal insulator and the adjacent insulator;
a second semiconductor layer provided on the first semiconductor layer;
a third semiconductor layer provided on the second semiconductor layer;
a fourth semiconductor layer connected to the second electrode in the second semiconductor layer; and
a fifth semiconductor layer provided between the first semiconductor layer and the first electrode.

5. The semiconductor device according to claim 4, wherein
the third semiconductor layer is not present in the terminal region.

6. The semiconductor device according to claim 1, further comprising a fourth electrode provided inside the terminal insulator, wherein
the thickness of the fourth electrode is thicker than the thickness of the third electrode.

7. The semiconductor device according to claim 1, wherein
the third electrode is electrically connected to the second electrode.

8. The semiconductor device according to claim 1, wherein
the semiconductor device is a MOSFET.

9. A semiconductor device, comprising:
a semiconductor portion having a cell region and a terminal region provided outside the cell region;
a first electrode provided on a rear surface of the semiconductor portion;
a second electrode provided on a front surface side of the semiconductor portion;
a control electrode provided in the semiconductor portion via one of a plurality of first insulators arranged in a direction from the cell region to the terminal region; and
a third electrode provided in the semiconductor portion via a second insulator between itself and the control electrode, wherein
the control electrode includes a first controller in contact with the first insulator, and a second controller in contact with the first insulator and opposed to the first controller via the second insulator, and
among the plurality of first insulators, an adjacent insulator adjacent to the terminal insulator provided closer to the terminal region than to the control electrode has a slope inclined toward the lower side of the first controller, and the concentration of impurities contained in the second controller provided in the slope is lower than the concentration of the impurities contained in other second controllers.

10. The semiconductor device according to claim 9, wherein
the material of the second controller provided in the slope is non-doped polysilicon.

11. The semiconductor device according to claim 9, wherein
in the adjacent insulator, the slope is opposed to the first controller via the second insulator, and the lower end of the second insulator is located lower than the lower end of the slope.

12. The semiconductor device according to claim 9, wherein
in the adjacent insulator, the slope is opposed to the first controller via the second insulator, and
the semiconductor device further comprises a third insulator provided between the slope and the third electrode.

13. The semiconductor device according to claim 9, wherein the semiconductor portion includes:
a first semiconductor layer provided with the terminal insulator and the adjacent insulator;
a second semiconductor layer provided on the first semiconductor layer;
a third semiconductor layer provided on the second semiconductor layer;
a fourth semiconductor layer connected to the second electrode in the second semiconductor layer; and
a fifth semiconductor layer provided between the first semiconductor layer and the first electrode.

14. The semiconductor device according to claim 9, wherein
the third semiconductor layer is not present in the terminal region.

15. The semiconductor device according to claim 9, further comprising a fourth electrode provided inside the terminal insulator, wherein
the thickness of the fourth electrode is thicker than the thickness of the third electrode.

16. The semiconductor device according to claim 9, wherein
the third electrode is electrically connected to the second electrode.

17. The semiconductor device according to claim 9, wherein
the semiconductor device is a MOSFET.
